(19) United States
(12) Patent Application Publication
(10) Pub. No.: US 2009/0212378 A1
(43) Pub. Date: Aug. 27, 2009

(54) Method for producing a micromechanical structural element and semiconductor arrangement

(75) Inventor: Franz Schrank, Graz (AT)

Correspondence Address: COHEN, PONTANI, LIEBERMAN & PAVANE LLP, 551 FIFTH AVENUE, SUITE 1210, NEW YORK, NY, 10176, US

(73) Assignee: AUSTRIAMICROSYSTEMS AG, Unterpremstatten (AT)

(21) Appl. No.: 11/920,660

(22) PCT Filed: May 19, 2006
(86) PCT No.: PCT/EP2006/004787

§ 371 Date: Apr. 1, 2009

(30) Foreign Application Priority Data
May 19, 2005 (DE) 10 2005 023 059.8

(51) Int. Cl. H01L 29/84; H01L 21/306

(52) U.S. Cl. 257/419; 438/53; 257/E21.219; 257/E29.324

(57) ABSTRACT

The method serves for producing a micromechanical structure element (13) on or in a crystal substrate (3), wherein the micromechanical structure element (13) is arranged in vibratable fashion in a recess (4) of the crystal substrate (3) and is connected to the crystal substrate (3) by means of a web (15), comprising the following steps: providing the crystal substrate (3); depositing an etching mask layer (1); locally removing the etching mask layer (1), such that the remaining etching mask layer (1) has a border (8) extending at a predeterminable angle φ of less than 180° on both sides of a connection region (19) of the web (15) to the crystal substrate (3), and etching the crystal substrate (3) in order to form the recess (4) and the micromechanical structure element (13). What is thereby achieved is that an uncovered crystal plane (7) runs through the connection region (19).

The present invention relates to a method for producing a micromechanical structure element, and a semiconductor arrangement.

Semiconductor arrangements comprising a micromechanical structure element are acceleration sensors, for example, in which a seismic mass is arranged in moveable fashion over a recess in the crystal substrate and the deflection is a measure of the acceleration of the seismic mass relative to the crystal substrate.

In semiconductor technology, thin-film technology and micromechanics, an etching mask layer serves to protect an underlying layer on a substrate, such that the layer to be protected is not removed upon immersion in an etching solution. At the locations at which the etching mask layer has an opening, the underlying layer is attacked by the etching solution and removed.

For the micromechanical patterning of silicon, etching solutions exist, such as potassium hydroxide for instance, which etch silicon at different rates in the different crystal directions. This is referred to as an anisotropic etching operation. In the case of a silicon crystal substrate, also called the silicon wafer, having a (100) crystal plane as surface of the crystal substrate, recesses whose sidewalls are (111) crystal planes arise during etching with potassium hydroxide. In this case, the symbols represented between parentheses are Miller indexes indicating the orientation of the crystal planes.

The etching masks for the anisotropic etching generally have rectangular structures. As shown in the book “Mikromechanik” [“Micromechanics”], Anton Heuberger, Springer Verlag, Berlin, 1991, page 345 and page 346 and also pages 349 to 354, self-supporting structures projecting into a recess can also be produced with various forms by means of an anisotropic etching. Examples of micromechanical structure elements in a semiconductor arrangement are cantilevers, spirals and bridges. The micromechanical structure element must be configured such that it is not attacked by the etching solution. The crystal substrate material situated underneath is etched away by the anisotropic etching solution until the etching attack is slowed down at a (111) crystal plane such that this can be referred to as an etching stop. The (111) crystal plane can therefore also be referred to as a stop plane.

A cantilever is often used for measuring an acceleration. The resonant frequency of a cantilever or of some other micromechanical structure element is dependent inter alia on the length of the etched-free micromechanical structure element. Therefore, it is very important for the length of a cantilever to be produced accurately during the anisotropic etching. The positioning of the etching mask in relation to the crystal planes is crucial for the accuracy. In the event of incorrect positioning by an angle other than zero, the recess is enlarged and the length of the cantilever increases. Such an incorrect arrangement can occur as a result of an erroneous alignment of an etching mask for the anisotropic etching at the so-called flat of the wafer. If the etching mask for the anisotropic etching is aligned at alignment crosses or other alignment structures that are already present on the wafer from preceding process steps, then the incorrect arrangement can also be caused by the erroneous alignment of that mask which serves for producing the alignment structures.

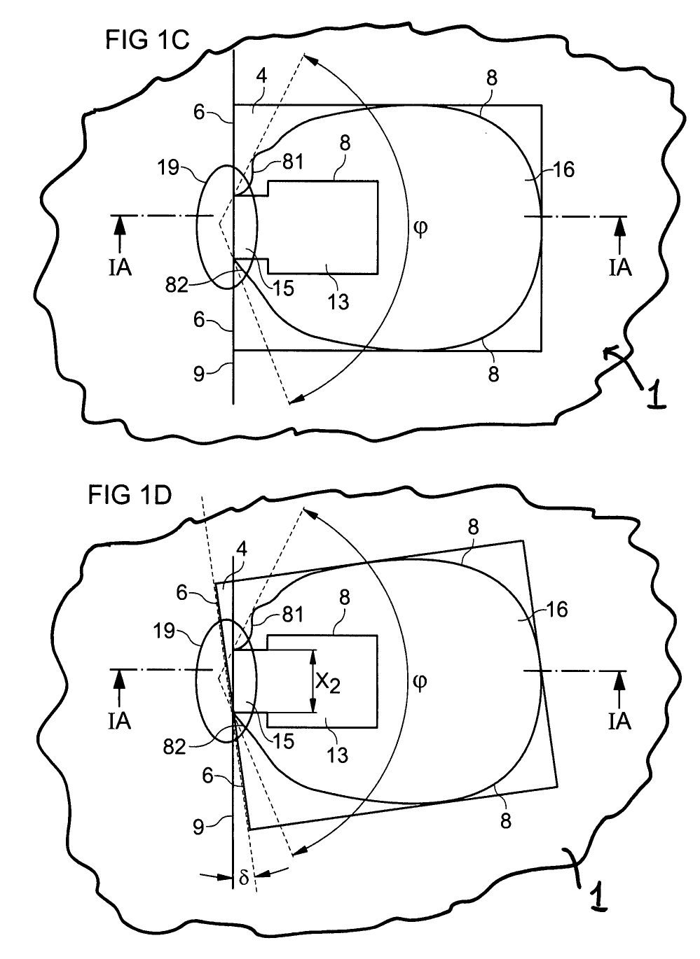

FIGS. 2A and 2B show plan views of a customary etching mask 1 for producing a micromechanical structure element 13 and of an etching result with incorrect arrangement with angular error.

FIG. 2A shows a plan view of an etching mask 1. In this exemplary arrangement, the micromechanical structure element 13 is embodied as a cantilever. The micromechanical structure element 13 projects into a recess 4 from an edge 9. A boundary 8 of the etching mask 1 has straight line segments and in this example forms a rectangle with a rectangular cantilever.

FIG. 2B shows a plan view of an etching result with an incorrect arrangement with an angular error δ. A line 6 therefore forms said angle δ with the edge 9. The etching operation stops only at one of the corners of the rectangle and not in the vicinity of the micromechanical structure element 13. The micromechanical structure element 13 therefore exhibits a significant undesirable undercut and thus has a longer length than envisaged.

The invention is based on the object of providing a method for etching free a micromechanical structure element from a crystal substrate and in the process of obtaining a high structural accuracy and also of providing a semiconductor arrangement having a micromechanical, structurally accurate structure element.

According to the invention, the object is achieved with regard to the method by means of a method for producing a micromechanical structure element on or in a crystal substrate, wherein the micromechanical structure element is arranged in vibratable fashion in a recess of a first main area of one of the two main areas of the crystal substrate, is connected to an edge of the recess of the crystal substrate by means of a web and has a main direction arranged approximately perpendicular to the edge, comprising the following steps:
providing the crystal substrate,
depositing an etching mask layer,
locally removing the etching mask layer, such that the remaining etching mask layer protects the micromechanical structure element to be formed and the web of said structure element against an etching attack and has a border having a first line section and a second line section, which extend from both sides of a connection region of the web to the crystal substrate and have a predeterminable angle φ of less than 180 degrees with respect to one another, and
etching the crystal substrate in order to form the recess and the micromechanical structure element, such that a line at which a crystal plane of the recess that has been uncovered by the etching touches the first main area of the crystal substrate runs through the connection region.

The method serves for producing the micromechanical structure element. The latter is situated on or in the crystal substrate. The micromechanical structure element is arranged in moveable fashion in the recess of the crystal substrate. It is restricted in its movement by virtue of the fact that the web connects the structure element to the edge of the recess of the crystal substrate. A part of the web, the edge and the adjacent region of the crystal substrate represent the connection region of the web.

The method comprises the following steps:

The crystal substrate is provided. It has two main areas, which are often also referred to as front side and rear side.

An etching mask layer is deposited on the entire first main area. If a layer construction is present on the first main area, then the etching mask layer is deposited on said layer construction.

The etching mask layer is patterned, such that it remains at the areas at which it is intended to afford protection against the etching attack. The etching mask layer protects at least the micromechanical structure element to be formed and the web of said structure element. It can also protect further structures on the surface against an etching attack. It determines the form of the recess. A main direction of the web is arranged approximately perpendicular to the edge. Likewise, the main direction of the micromechanical structure element is arranged approximately perpendicular to the edge.

At the locations at which the etching mask layer was removed, an etching attack area is uncovered.

The remaining etching mask layer has the border. The latter comprises the border of the micromechanical structure element and of the web apart from the transition from the web to the crystal substrate. Proceeding from the border of the web, the border comprises the first line section on one side of the web and the second line section on the other side of the web, the lines being continued such that they form at least one closed area in order to enable an etching attack.

These two lines extend at a predeterminable angle φ of less than 180 angular degrees on both sides of a connection region of the web to the crystal substrate. The tangents at points of these two lines meet in the etching mask layer situated above the crystal substrate, and intersect there at an angle φ of less than 180 angular degrees.

The first line section is arranged on one side and the second line section is arranged on a further side of the connection region. The first line section is connected to the border of one side of the web and the second line section is connected to the border of a further side of the web. The two line sections have the predeterminable angle φ of less than 180 degrees with respect to one another.

In one embodiment, the two line sections lie at least in sections on the legs of an angle whose vertex is arranged in the remaining etching mask layer and has the predeterminable angle φ of less than 180 degrees.

The crystal substrate is etched by means of an anisotropically acting etching solution. The removal of the crystal substrate by the etching solution starts on the etching attack area. In this case, the recess is formed and the micromechanical structure element is uncovered.

The recess comprises a plurality of lateral areas each formed by one of the uncovered crystal planes. At that edge of the recess at which the web is uncovered, one of the crystal planes together with the surface of the crystal substrate forms the line. The result is that the line runs through the connection region of the web to the crystal substrate.

What is achieved by choosing the angle to be less than 180 angular degrees is that in the event of an angular error between etching mask layer and the crystal planes present in the crystal substrate or the lines at which said planes touch the first main area of the crystal substrate, the etching operation is slowed down by virtue of the fact that one of the slowly etchable crystal planes is uncovered, whose line at which said crystal plane touches the first main area runs through the connection region of the web. Said crystal plane can no longer be attacked “from the side” since it is protected against an attack from the first main area of the crystal substrate by the etching mask layer and it cannot be attacked from another side since together with the other slowly etchable crystal planes it forms the sidewalls of the recess.

Without the form of the border with the angle of less than 180 angular degrees, even a slowly etchable crystal plane that runs through the connection region is etched further, although it is protected against an attack from the first main area in the connection region, since it is attacked laterally. In the case of a rectangular form of the border of the etching attack area, the etching operation only stops when the slowly etchable crystal plane has reached the corner of the rectangle.

One advantage of this method is that in the connection region of the web of the micromechanical structure element, the line at which the uncovered crystal plane touches the first main area runs in such a way that the etching process is slowed down there in such a way that an etching stop actually occurs. The method achieves this even when the etching mask layer is arranged erroneously by an angle during the production sequence. What is therefore advantageously achieved is that a micromechanical structure element is situated with high accuracy at the edge of the recess. The influence of the variation occurring during the alignment of the etching mask and the variation occurring when applying the so-called flats at the wafers is significantly reduced.

The lateral areas of the connection region can comprise an area with an area normal essentially parallel to the main direction of the micromechanical structure element, an area with an area normal parallel to the area normal of the first main area, an area with an area normal oppositely parallel to the area normal of the first main area, an area in the direction of the crystal substrate and two areas with mutually opposite area normals which are approximately parallel to the edge. The first line section passes through one of the latter two areas and the second line section passes through another of the latter two areas.

In one embodiment, the first line section is situated on a first straight line and the second line section is situated on a second straight line, which form the legs of the angle having the predeterminable value φ of less than 180 degrees.

The vertex of the angle is preferably arranged in the remaining etching mask layer.

In this embodiment, the first and the second line section are in each case formed as a straight line section. As an alternative, small undulations or fine steps brought about by the method for producing a photomask, serving for structurally predefining the etching mask layer, by means of optical pattern generator or electron beam writer can be superimposed on the two straight line sections.

In one embodiment, the first and the second line section in each case have a second predeterminable angle γ with respect to the edge.

In one embodiment, depositing at least one layer serves to produce the construction of the micromechanical structure element. Further layers can be deposited. At least one of the layers can be patterned photolithographically. In one advantageous embodiment, that side of the micromechanical structure element which faces the recess is protected against the attack by the etching solution.

In one embodiment, in which the crystal substrate is formed from silicon having a (100) crystal plane as main area, the plurality of lateral areas which are encompassed by the recess and which are in each case formed by one of the uncovered crystal planes are formed by four (111) stop planes, the symbols represented between parentheses being Miller indexes.

After the anisotropic etching, the etching mask layer can be removed. The etching mask layer is advantageously left on the surface since the etching mask layer is a highly resistant layer and can therefore be used as passivation of the micromechanical structure element during operation.

With regard to developments of the method, reference is made to the subclaims.

The object is achieved with regard to the arrangement by means of a semiconductor arrangement having an etching mask layer, for producing a micromechanical structure element on or in a crystal substrate, wherein the micromechanical structure element is arranged in vibratable fashion in a recess of a first main area of one of the two main areas of the crystal substrate, is connected to an edge of the recess of the crystal substrate by means of a web and has a main direction arranged approximately perpendicular to the edge, and the etching mask layer is equipped for protecting the micromechanical structure element and the web thereof and has a border having a first line section and a second line section, which extend on both sides of a connection region of the web to the crystal substrate and have a predeterminable angle φ of less than 180 degrees with respect to one another, such that a line at which an uncovered crystal plane of the recess touches the first main area of the crystal substrate runs through the connection region.

The etching mask layer comprises a material which cannot be completely etched away during the etching time, such as, for instance, a photoresist or a thin film. The crystal substrate, such as a silicon wafer for instance, has two main areas. The etching mask layer is arranged on the first main area. At least one interlayer can be provided between the crystal substrate and the etching mask layer.

The micromechanical structure element extends over or into the recess. It is connected to the crystal substrate via the web. A main direction of the web is approximately perpendicular to the edge. Likewise, the main direction of the micromechanical structure element is approximately perpendicular to the edge. The connection region comprises parts of the web and the crystal substrate in the vicinity of the edge.

The etching mask layer serves for anisotropically etching the recess in the crystal substrate and etching free the micromechanical structure element. The recess arises through the action of the anisotropic etching solution on an etching attack area. The covering of the web and of the micromechanical structure element by the etching mask layer serves to protect the web and the structure element.

The separating line between the etching attack area and the etching mask layer is the border. The border predefines the area on which the etching solution carries out the etching operation. The crystal substrate has various crystal planes coming to the surface. However, in the course of the etching operation, the crystal planes that can be rapidly removed by the etching solution can be decomposed and the recess produced at the end has only the crystal planes that can be etched very slowly by the etching solution.

The border of the micromechanical structure element forms a part of the border. The border is continued in such a way that the etching attack area arises. The border comprises a first line section on one side of the connection region and a second line section on a further side of the connection region. The line at which the uncovered crystal plane touches the first main area and which does not lie on the envisaged edge arises in the event of the misalignment of the border of the etching mask layer by an angle other than zero.

Let the maximum angle to be assumed in respect of the misalignment between the etching mask and the line at which the uncovered crystal plane touches the first main area be γ. The predeterminable angle φ assumed by the border in the connection region on both sides of the web or by the first and the second line section with respect to one another is thus 180 angular degrees minus twice the angle γ.

After the anisotropic etching operation in the event of a misalignment of the etching mask with respect to the line with an angle δ, the line and the edge are situated at the angle δ with respect to one another.

If the uncovered crystal plane and the first main area of the crystal substrate touch on the line which passes through the connection region and the continuation of which in the form of a straight line does not intersect the border of the etching attack area outside the connection region, there is no longer a possibility of etching attack, which has the effect that the crystal plane that can be etched slowly can be etched further by attack from another direction.

One advantage of this arrangement is that the line passes through the connection region of the web, to be precise even when the etching mask is arranged erroneously by an angle δ during the production sequence.

The arrangement with the border of the etching mask layer forming an angle φ of less than 180 angular degrees affords a significant advantage over conventional etching masks that only know rectangular structures. In the case of a rectangular boundary of the etching mask, the result is a stop of the etching process at one of the corners of the rectangle rather than as desired in the connection region of the web and thus of the micromechanical structure element.

In one development, the value of the angle between the edge and the border on one side of the web can be equal to the value of the angle between the edge and the border on the second side of the web, namely equal to γ, a value greater than the value of the area angle δ being provided for the further predeterminable angle γ.

In one development, the value of the angle between the edge and the border on one side of the web can be different from the value of the angle between the edge and the border on the second side of the web. It is thus advantageously possible to take account of different tolerances of the micromechanical structure element to be etched free with regard to the rotational sense of the incorrect arrangement.

The entire micromechanical structure element can be embodied as a web.

In one development, the micromechanical structure element described above is altered to the effect that it is divided into two partial structure elements. Thus, one partial structure element is connected to the crystal substrate by means of the web and the second partial structure element is connected to the crystal substrate by means of a further web in the same direction as the web. A common connection region is formed. The lines of the border which leave the common connection region form an angle of less than 180 angular degrees. What is thus achieved is that the line at which the crystal plane uncovered by the anisotropic etching operation touches the first main area of the crystal substrate runs through the common connection region.

In another development, the micromechanical structure element can have an opening which has at least one point in common with the edge. Consequently, the micromechanical structure element has the web and the further web in the same direction, which together with the edge and the adjacent crystal substrate form the common connection region. The border forms an angle φ of less than 180 angular degrees. Thus, even in the event of a misalignment of the etching mask relative to the line, the line runs through the common connection region and the micromechanical structure element can be produced with high accuracy.

In one development, a micromechanical structure element projects into the recess from the edge and at least one further edge. The web has the connection region and at least one further web has at least one further connection region. The etching mask layer is preferably designed in such a way that the border in the region of the connection region forms an angle φ of less than 180 angular degrees and the border in at least one region of the at least one further connection region forms an angle φ′ of less than 180 angular degrees. The at least one further uncovered crystal plane touches the first main area at at least one further line. Thus, the line runs in the connection region and the at least one further line runs in the at least one further connection region.

In this case, one advantage of this design of the etching mask is that even in the event of an incorrect arrangement of the etching mask relative to the at least one further line, the latter runs through the at least one further connection region after the anisotropic etching.

The border of the etching mask can be a closed line having any desired line form in further sections. The border defines the desired recess.

In an advantageous manner because it is simpler in terms of design, a first straight line segment comprises the border in the vicinity of the connection region on one side of the web and a further straight line segment comprises the border on the second side of the web. Since two straight line segments cannot encompass an area, at least one further straight line segment can be provided.

These straight line segments advantageously form a predeterminable angle φ of less than 180 angular degrees with a value for φ which amounts to 180 angular degrees minus twice the further predeterminable angle γ. For this means that the area at which the etching attack by the etching solution can take place is provided such that it is as large as possible. A short etching time can be achieved as a further advantage.

The further predeterminable angle φ′ can be the predeterminable angle φ. However, if the function of the micromechanical structure element in one exemplary embodiment requires the line to be situated in the connection region with higher accuracy than the further line in the further connection region, then the angles can be predeterminable such that they are different. A smaller value φ of the predeterminable angle than a value φ′ of the further predeterminable angle can be provided in this case.

It is preferred for the value of the predeterminable angle φ and the value of the further predeterminable angle φ′ to be between 160 and 180 angular degrees, but to be different from 180 angular degrees.

It is furthermore preferred for the value of the predeterminable angle φ and the value of the further predeterminable angle φ′ to be between 170 and 180 angular degrees, but to be different from 180 angular degrees.

An etching mask layer preferably comprises a material which cannot be completely etched away during the etching time. That side of the structure element to be etched free which faces the recess also preferably comprises a layer which cannot be completely etched away during the etching time. Likewise, that side of the structure to be etched free which is remote from the recess and the areas in the surface of the crystal substrate outside the recess preferably comprise a layer which cannot be completely etched away during the etching time.

The etching mask layer can be designed, inter alia, for silicon Si, gallium arsenide GaAS, gallium phosphide GaP or indium phosphide InP as material of the crystal substrate.

The etching mask layer can be formed from photoresist. In an advantageous manner since it is more resistant to an anisotropic etching solution, the etching mask layer is composed of silicon oxynitride or silicon dioxide. The etching mask layer preferably comprises silicon nitride or silicon carbide because these have very low etching rates. The etching mask layer can comprise a combination of materials. The etching mask layer can comprise a double layer. It can comprise for example a silicon oxide layer covered with a silicon nitride layer.

The material of the etching mask layer can be different at different surfaces. By way of example, the largest proportion of the area of the surface can be protected with silicon carbide, while the electrical contact connections are covered with gold.

In the case of silicon as material of the crystal substrate, depending on the anisotropic etching solution, that side of the structure to be etched free which faces the recess can comprise a layer composed of highly boron-doped silicon, silicon nitride, silicon carbide or silicon oxide.

If the crystal substrate comprises p-doped silicon and that side of the structure to be etched free which faces the recess comprises n-doped silicon, the etching apparatus can be designed for the blocking of this pn junction during the etching process by applying a positive voltage to the n-doped silicon relative to the etching solution. By means of this blocked pn junction it is possible to obtain an etching stop at the n-doped layer.

The micromechanical structure element can comprise one layer. However, it can also comprise a plurality of layers in order to fulfil a function. At least one of the layers can be patterned.

By way of example, the micromechanical structure element comprises a first layer composed of an insulator material such as silicon nitride. A polysilicon layer is deposited over the silicon nitride layer, and is patterned by means of photolithography and an etching operation in such a way that a polysilicon resistor is formed. An electrical contact to the polysilicon resistor can be produced by means of further layers composed of metal, for example, which are first deposited and then patterned. An etching mask layer composed of silicon nitride, for instance, covers the micromechanical structure element and exhibits a protective effect against an attack by the anisotropic etching solution. The etching mask layer can be etched away after the end of the anisotropic etching operation. It can advantageously remain as passivation for the operation of the micromechanical structure element on said structure element.

The resistance of polysilicon resistors is dependent on the mechanical stress. A movement of the structure element relative to the crystal substrate thus alters the resistance of a polysilicon resistor provided in the region of the highest stress. The micromechanical structure element can therefore be designed as an acceleration sensor.

On those areas of the first main area at which the anisotropic etching operation is to start, it is possible to remove not only the etching mask layer but also all interlayers or layers which are deposited for the formation of the micromechanical structure element or of at least one further structure over the whole area on the first main area or on the layers present there.

The crystal substrate can comprise silicon with a surface comprising a (100) crystal plane. If the desired recess is intended to have perpendicular walls, the crystal substrate can comprise silicon with a surface comprising a (110) crystal plane. In this case, the symbols represented between parentheses are Miller indexes indicating the crystal planes.

In one development, the micromechanical structure element comprises a moveable sensor element, which is connected to a crystal substrate, and is applied at least in regions directly on the crystal substrate. In one embodiment of the development, the moveable sensor element can comprise silicon at the location at which the moveable sensor element is applied on the crystal substrate. The micromechanical structure element is advantageously produced with a small undercut according to the proposed method because this means that the silicon is not uncovered and etched away at this location. An undesirable etching away of the silicon at this location could mean a failure of the sensor element. An exemplary arrangement with such a sensor element and a method in this respect are described in the earlier patent application DE 102005002304.5, which is hereby incorporated by reference in the present disclosure in this regard.

With regard to developments of the arrangement, reference is made to the subclaims.

To summarize, the proposed principle has the following advantages, inter alia:
a significantly increased accuracy in the production of a structure to be etched free even in the event of an incorrect positioning of the etching mask by an angle relative to the line at which the uncovered crystal plane touches the first main area of the crystal substrate, and hence a significantly reduced undercut of the micromechanical structure element to be etched free,
a higher tolerance in the alignment of the etching mask relative to the crystal orientation,
a greater tolerance in the specification for the crystal orientation of the surface of the crystal substrate and for the application of the so-called flat.

The invention is explained in more detail below on the basis of a plurality of exemplary embodiments with reference to the figures. Components, structure parts or structure elements that are functionally identical or identical in terms of their effect bear identical reference symbols.

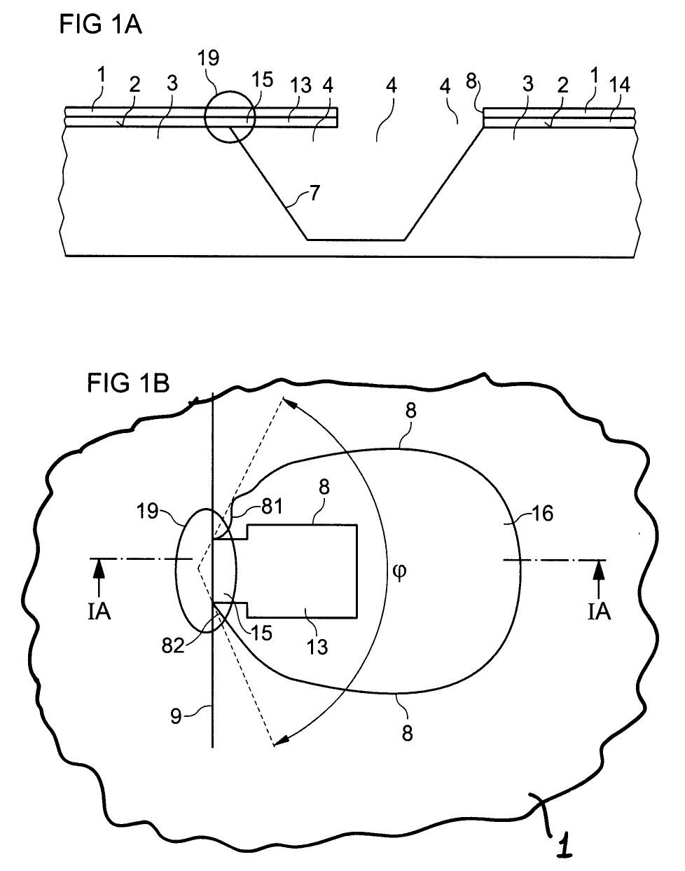

FIGS. 1A to 1D show an exemplary cross section of a semiconductor arrangement comprising a crystal substrate, a micromechanical structure element and an etching mask layer and also exemplary plan views of an etching mask layer for the micromechanical structure element and of the etching result without and with incorrect arrangement with angular error according to the principle proposed.

FIGS. 2A and 2B show plan views of a customary etching mask and of the etching result with incorrect arrangement with angular error.

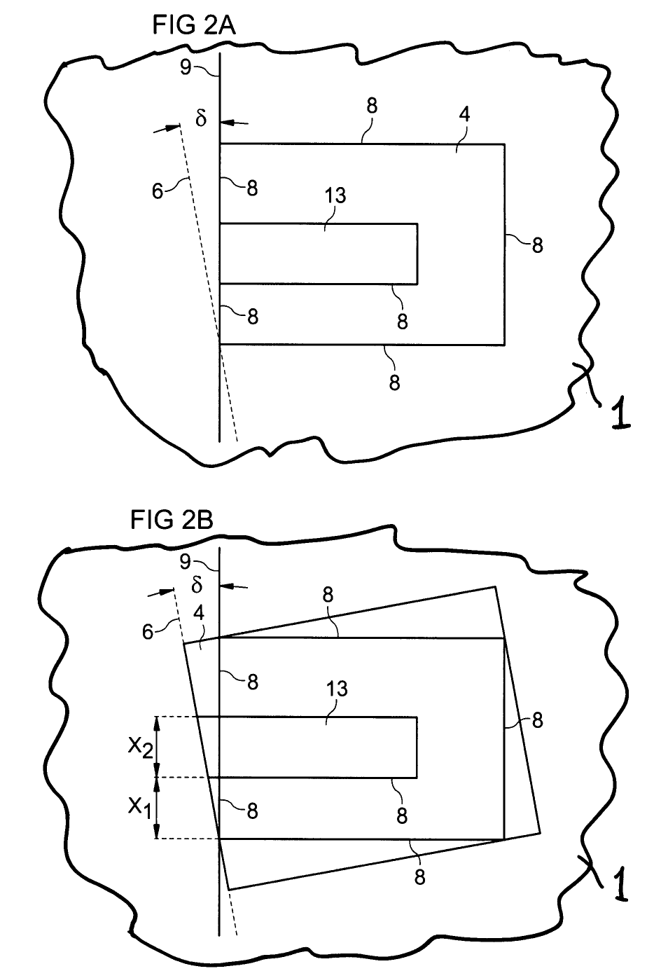

FIG. 3 shows an exemplary embodiment according to the principle proposed of a plan view of an etching mask layer for producing a micromechanical structure element which is to be etched free and which has a plurality of webs in the same direction.

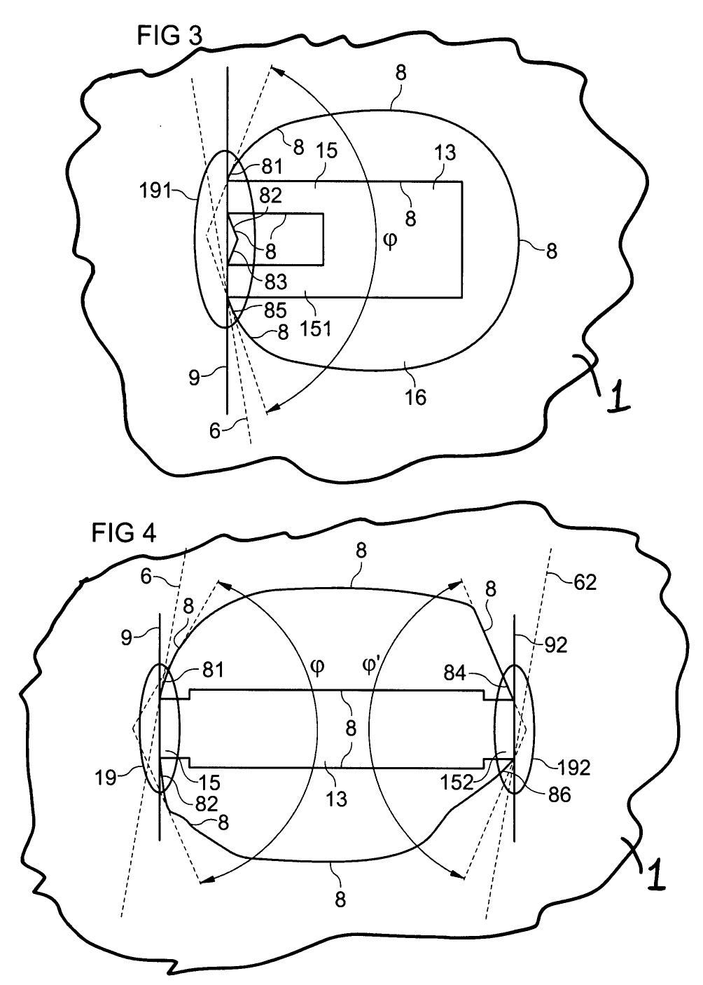

FIG. 4 shows an exemplary embodiment of a plan view of an etching mask layer for producing a micromechanical structure element in the form of a bridge having a web to one edge and a further web to a further edge, according to the principle proposed.

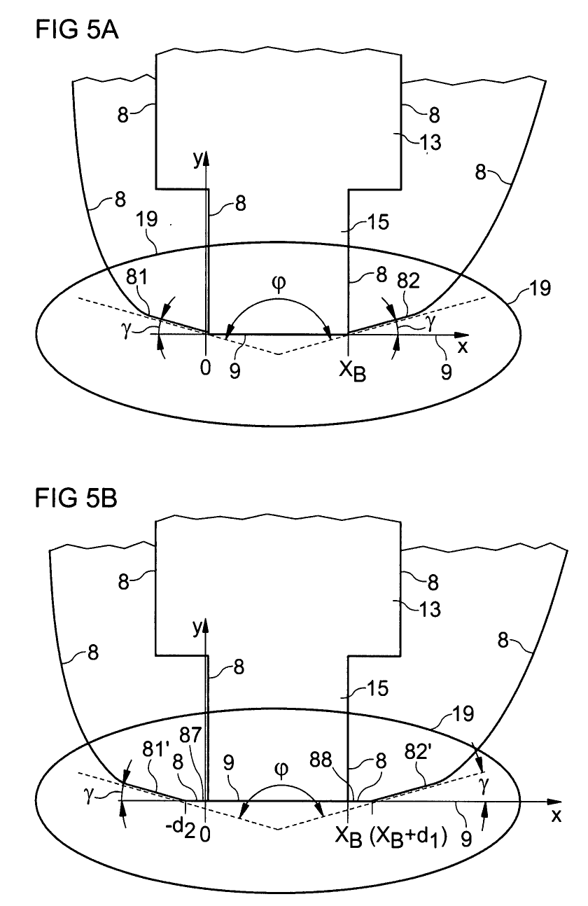

FIGS. 5A and 5B show two developments of the etching mask layer 1 with the border 8 in or in the vicinity of the connection region 19 according to the principle proposed.

FIGS. 1A to 1D show a cross section through a semiconductor arrangement and also exemplary plan views of an etching mask layer 1 for a micromechanical structure element 13 and of etching results without and with incorrect arrangement with an angular error δ according to the principle proposed.

FIG. 1A shows a cross section of the exemplary semiconductor arrangement with a crystal substrate 3, the micromechanical structure element 13 to be etched free, and also the etching mask layer 1. The position of the cross section is depicted in FIG. 1B. At some locations an interlayer 14 is situated between a first main area 2 of the crystal substrate 3 and the etching mask layer 1. The micromechanical structure element 13 projects into the recess 4. The recess 4 is formed at one side from a crystal plane 7.

The etching mask layer 1, which covers a side of the micromechanical structure element 13 which is remote from the recess 4 and the further areas on the surface 2 outside the recess 4 and protects them against the etching attack, advantageously comprises a layer which is not completely etched away during the etching time.

That side of the micromechanical structure element 13 which faces the recess 4 preferably comprises a layer which is not completely etched away during the etching time. In the case of silicon as material of the crystal substrate 3, said layer can comprise a highly boron-doped silicon, silicon nitride, silicon carbide or silicon oxide.

The micromechanical structure element 13 comprises at least one layer. The micromechanical structure element 13 can comprise a semiconductor material. The semiconductor material can be a material of the crystal substrate which is protected by special precautions against being etched away by the anisotropic etching solution. The semiconductor material can also be depositable as a layer over the surface of the crystal substrate.

The micromechanical structure element 13 can comprise at least one conductive layer. Said conductive layer can be composed of at least one metal. In an advantageous manner because it can be deposited with higher temperatures, a conductive layer can be composed of polysilicon. The micromechanical structure element 13 can comprise at least one insulating layer. At least one of said layers can be patterned.

FIG. 1B shows a plan view of the exemplary etching mask layer 1 according to the principle proposed. In this exemplary arrangement, the micromechanical structure element 13 is embodied as a cantilever. It has a web 15, by means of which the structure element 13 is connected to the edge 9 of the crystal substrate 3. The micromechanical structure element 13 projects into the recess 4 from the edge 9. The web 15, the edge 9 at the transition from the web 15 to the crystal substrate 3 and an adjacent part of the crystal substrate 3 form a connection region 19. In this exemplary embodiment, the border 8 of the etching mask layer 1 comprises straight line portions for the micromechanical structure element 13 and further lines without straight line portions. The lines enclose an area at which the etching attack takes place. The border 8 comprises a first line section 81, which is connected to the border of the web 15 on one side of the web 15, and a second line section 82, which is connected to the border of the web 15 on the further side of the web 15.

The etching mask layer 1 is embodied in such a way that the border 8 on both sides of the web forms an angle φ of less than 180 angular degrees.

FIG. 1C shows a plan view of the etching result without incorrect arrangement. The uncovered crystal plane 7 and the first main area 2 touch on the line 6. The line 6 lies on the edge 9, such that the micromechanical structure element 13 projects into the recess 4 without an undesirable undercut.

FIG. 1D shows a plan view of an etching result with an incorrect arrangement with an angular error δ of less than the predeterminable angle γ. The line 6 forms an angle δ with the edge 9. Therefore, from the micromechanical structure element 13 to be etched free, only one side of the web ends on the line 6. The second side of the web lies completely over the recess 4.

One advantage of an etching mask 1 according to the principle proposed is that the boundary 8 of the etching mask layer 1 is angled in such a way that at least one of the sides of the web 15 extends as far as the line 6. Thus, no undesirable undercut of a micromechanical structure element 13 to be etched free is present at one of the two sides of the web 15 and an undercut that is significantly smaller in comparison with a customary arrangement, as illustrated in FIGS. 2A and 2B, is present at the further side of the web 15.

FIGS. 2A and 2B show plan views of a customary etching mask 1 for producing the micromechanical structure element 13 to be etched free, and of the etching result with incorrect arrangement with angular error. FIGS. 2A and 2B have been explained in the introduction to the description, such that the explanation is not repeated at this juncture. In accordance with the arrangement in FIG. 1B, there is no undercut at one side of the web 15 in FIG. 1D. The undercut at the second side of the web 15 amounts to x₂*sin(δ), where x₂ is the distance between the first side and the second side, and δ is the angle of the incorrect arrangement of the etching mask with respect to the line 6.

In FIG. 2B, at the first side of the web 15, the undercut amounts to x₁*sin(δ), where x₁ is the distance between the corner of the rectangle in the border 8 and the first side of the web 15, and δ is the angle of the incorrect arrangement of the etching mask with respect to the line 6. The undercut at the second side amounts to (x₁+x₂)*sin(δ), where x₁, x₂ and δ are defined without any change.

The effect of an etching mask layer 1 in accordance with FIG. 1B is, therefore, that the micromechanical structure element 13 in FIG. 1B has a significantly smaller undesirable undercut than the micromechanical structure element 13 in FIG. 2B.

FIG. 3 shows a plan view of the exemplary etching mask layer 1 according to the principle proposed for producing the micromechanical structure element 13 which is to be etched free and which has the web 15 and a further web 151, which both connect the structure element 13 to the crystal substrate 3 via the edge 9. The further web 151 therefore points in the same main direction as the web 15. The main directions of the two webs 15, 151 and the main direction of the micromechanical structure element 13 are approximately perpendicular to the edge 8. The further web 151 can have a border in the form of lines that are parallel to the lines of the border of the web 15. Depending on the function of the micromechanical structure element 13, the border of the web 15 and the border of the further web 151 can have non-parallel lines.

A common connection region 191 comprises parts of the web 15, of the further web 151 and of the crystal substrate 3 in the vicinity of the transition or the edge 9. The border 8 leaving the common connection region 191 on both sides forms an angle φ of less than 180 angular degrees and has two line sections 81, 85 lying in the vicinity of the border of the webs 15, 151 on the legs of the angle φ of less than 180 angular degrees. The vertex of the angle lies on the remaining etching mask layer.

The border 8 is depicted as a line having partial straight line segments. The border 8 of the etching mask layer 1 proposed ensures that the line 6 runs through the common connection region 191. At least one side of the web 15 or of the further web 151 have a point in common with the line 6.

One advantage of an etching mask 1 according to the principle proposed is that the accuracy in the production of this structure element is significantly improved, by virtue of the fact that the line 6 runs through the common connection region 191.

The border 8 between the web 15 and the further web 151 cannot, however, be situated on that half plane of the edge 9 which is opposite the structure element 13 to be etched free. In this case, the edge 9 would be determined by one of said points of the border 8 between the web 15 and the further web 151. The border 8 between the two webs 15, 151 has the line sections 82, 83.

FIG. 4 shows a plan view of the exemplary etching mask layer 1 according to the principle proposed for producing a micromechanical structure element 13 to be etched free in the form of a bridge, which is connected to the edge 9 of the recess 4 of the crystal substrate 3 by means of the web 15 and to a further edge 92 of the recess 4 of the crystal substrate 3 by means of a further web 152. The main direction of the micromechanical structure element 13 is approximately perpendicular to both edges 9, 92. The main direction of the web 15 is approximately perpendicular to the edge 9 and the main direction of the further web 152 is approximately perpendicular to the further edge 92.

The web 15 and an adjacent part of the crystal substrate 3 form the connection region 19; analogously thereto, the further web 152 and an adjacent part of the crystal substrate 3 form a further connection region 192. Analogously to the border 8 in the vicinity of the connection region 19, the border 8 extending on both sides of the further connection region 192 forms an angle φ′ of less than 180 angular degrees. In this exemplary embodiment, the border 8 comprises straight line segments and other line forms. The border 8 has the first and the second line section 81, 82 in the connection region 19 and also a further first and a further second line section 84, 86 in the further connection region 192.

Silicon having a (110) crystal surface is preferably used as crystal substrate 3 for producing a bridge as micromechanical structure element 13. In this case, the symbols represented between parentheses are Miller indexes indicating the orientation of the crystal planes.

The bridge can therefore advantageously be etched free with high accuracy.

FIGS. 5A and 5B show two developments of the etching mask layer 1 with the border 8 in or in the vicinity of the connection region 19.

FIG. 5A shows the web 15 and the micromechanical structure element 13 and also the border 8 in an x-y coordinate system. The web undergoes transition into the edge 9 of the crystal substrate 3 at the x axis between the points y=0 and x=0 and also y=0 and x=x_{B}. The main direction of the micromechanical structure element 13 and the main direction of the web 15 are in the direction of the y coordinate axis and thus perpendicular to the edge 9. The border 8 runs along the web 15 and the micromechanical structure element 13. In order that the border 8 forms a closed area, the border 8 comprises further lines lying on the following region, when the areas of the web 15 and of the micromechanical structure element 13 are to be excluded:

y≧0 for 0<x<x_{B};

y≧(x−x_{B})·tan γ for x_{B}≦x;

y≧−x·tan γ for x≦0

where x_{B}>0

Instead of the tan γ of a further predeterminable angle γ it is also possible to choose the sin γ since, given the small angles γ, the values for tan γ and sin γ differ only little.

The further predeterminable angle γ is in the following relationship with the predeterminable angle φ:

φ+2 γ=180°

The first line section 81 has x coordinates where x≦0 and y coordinates where y≧−x tan γ, and the second line section 82 has x coordinates where x≧x_{B} and y coordinates where y≧(x−x_{B}) tan γ. The first and the second line section 81, 82 lie in sections on a first and a second straight line having the predeterminable angle φ of less than 180 degrees with respect to one another. The first straight line passes through the point having the coordinates x=0 and y=0, and the second straight line passes through the point having the coordinates x=x_{B} and y=0. The vertex of the angle lies on the remaining etching mask layer and has a y coordinate where y<0 and an x coordinate where 0<x<x_{B}.

Since the border 8 outside the border of the web 15 and of the micromechanical structure element 13 only has points having y and x coordinates according to the above formulae, either the point y=0 and x=0 or the point y=0 and xₓ_{B} lies on the line 6. The web 15 therefore has no undercut at one side.

FIG. 5B shows, as in FIG. 5A, the web 15 and the micromechanical structure element 13 and also the border 8 in an x-y coordinate system. The web undergoes transition into the edge 9 of the crystal substrate 3 at the x axis between the points y=0 and x=0 and also y=0 and x=x_{B}. The border 8 runs along the web 15 and the micromechanical structure element 13.

In order that the border 8 forms a closed area, the border 8 comprises further lines. The boundary 8 advantageously comprises short straight lines 87, 88 lying on the edge 9 or near the edge 9. After the two short lines 87, 88, the border 8 comprises the first and the second line section 81′, 82′. The first and the second line section 81′, 82′ lie in sections on two straight lines having the predeterminable angle φ of less than 180 degrees with respect to one another. As in FIG. 5A, the vertex of the angle lies on the remaining etching mask layer. One advantage of this arrangement is that the area at which the etching attack takes place is enlarged as a result, without the undesirable undercut and lengthening of the web increasing significantly in this case.

In accordance with this development, the border 8 can lie on the following region, wherein the areas of the web 15 and of the micromechanical structure element 13 are to be excluded:

y≧0 for −d₂<x<x_{B}+d₁;

y≧(x−x_{B}−d₁)·tan γ for x_{B}+d₁≦x;

y≧−(x+d₂)·tan γ for x≦d₂

where d₁>0 and d₂>0

Since the border 8 outside the border of the web 15 and of the micromechanical structure element 13 only has points having y and x coordinates according to the above formulae, either the point y=0 and x=−d₂ or the point y=0 and xₓ_{B}+d₁ lies on the line 6. The web 15 therefore has only a very small undercut at one side and a somewhat larger undercut at the other side.

### LIST OF REFERENCE SYMBOLS

1 Etching mask layer

2 First main area

3 Crystal substrate

4 Recess

6 Line

62 Further line

7 Crystal plane

72 Further crystal plane

8 Border

81, 81′ First line section

82, 82′ Second line section

83, 84 Further first line section

85, 86 Further second line section

87, 88 Short line

9 Edge

92 Further edge

13 Micromechanical structure element

15 Web

151 Further web

152 Further web

16 Etching attack area

19 Connection region

191 Common connection region

192 Further connection region

x₁ Distance

x₂, x_{B} Width

d₁, d₂ Distance

γ Further predeterminable angle

δ Angular error

φ, φ′ Predeterminable angle

1-22. (canceled)

23. A method for producing a micromechanical structure element on or in a crystal substrate, wherein the micromechanical structure element is arranged in vibratable fashion in a recess of a first main area of one of the two main areas of the crystal substrate, is connected to an edge of the recess of the crystal substrate by means of a web and has a main direction arranged approximately perpendicular to the edge, comprising the steps of:
providing the crystal substrate;
depositing an etching mask layer;
locally removing the etching mask layer, such that the remaining etching mask layer protects the micromechanical structure element to be formed and the web of said structure element against an etching attack and has a border having a first line section and a second line section, which extend from both sides of a connection region of the web to the crystal substrate and have a predeterminable angle φ of less than 180 degrees with respect to one another, in order to obtain a high structural accuracy of the micromechanical structure element; and
etching the crystal substrate in order to form the recess and the micromechanical structure element, such that a line at which a crystal plane of the recess that has been uncovered by the etching touches the first main area of the crystal substrate runs through the connection region;
wherein the predeterminable angle φ is defined from an interval of more than 160 and less than 180 angular degrees.

24. The method according to claim 23, in which the etching mask layer is removed in such a way that the remaining etching mask layer additionally protects at least one further web, which extends in the same direction as the web and by means of which the micromechanical structure element to be formed is additionally connected to the edge of the recess of the crystal substrate, against the etching attack and has the border extending at the angle φ of less than 180 degrees on both sides of the common connection region of the web and of the at least one further web to the crystal substrate, such that the line at which the uncovered crystal plane of the recess touches the first main area of the crystal substrate runs through the common connection region.

25. The method according to claim 23, in which the etching mask layer is removed in such a way that the remaining etching mask layer additionally has at least one further web, by means of which the micromechanical structure element to be formed is connected to at least one further edge of the recess of the crystal substrate, and the border extending at a further angle φ′ of less than 180 degrees on both sides of at least one further connection region of the at least one further web to the crystal substrate, such that at least one line at which at least one further uncovered crystal plane of the recess touches the main area of the crystal substrate runs through the at least one further connection region.

26. The method according claim 23,
comprising determining the border in the connection region such that it is straight in sections.

27. The method according to claim 23,
wherein the predeterminable angle φ from an interval of more than 170 and less than 180 angular degrees.

28. The method according to claim 23,
comprising using material of the crystal substrate for producing the micromechanical structure element.

29. The method according to claim 23,
comprising depositing layers on the crystal substrate for producing the micromechanical structure element.

30. The method according to claim 23,
comprising providing the crystal substrate comprising silicon, gallium arsenide, gallium phosphide or indium phosphide.

31. The method according to claim 23,
comprising providing one or more substances from the set consisting of potassium hydroxide, sodium hydroxide, lithium hydroxide, ammonium hydroxide, ethylene diamine pyrocatechol with admixture of water, pyrocatechol and pyrazine, hydrazine with water or tetramethylammonium hydroxide as etching solution for etching the crystal substrate (3).

32. The method according to claim 23,
comprising providing the crystal substrate comprising silicon having a (100) or (110) wafer orientation.

33. A semiconductor arrangement having an etching mask layer, for producing a micromechanical structure element on or in a crystal substrate, wherein the micromechanical structure element is arranged in vibratable fashion in a recess of a first main area of one of the two main areas of the crystal substrate, is connected to an edge of the recess of the crystal substrate by means of a web and has a main direction arranged approximately perpendicular to the edge, and the etching mask layer is equipped for protecting the micromechanical structure element and the web thereof and has a border having a first line section and a second line section, which extend on both sides of a connection region of the web to the crystal substrate and have a predeterminable angle φ of less than 180 degrees with respect to one another, in order to obtain a structurally accurate micromechanical structure element such that a line at which an uncovered crystal plane of the recess touches the first main area of the crystal substrate runs through the connection region, wherein the predeterminable angle φ is between 160 and 180 angular degrees.

34. A semiconductor arrangement according to claim 33,
wherein
the etching mask layer is equipped for protecting at least one further web in the same direction as the web, via which the micromechanical structure element is additionally connected to the edge of the recess of the crystal substrate, against the etching attack and has the border extending at the predeterminable angle φ of less than 180 degrees on both sides of the common connection region of the web and of the at least one further web in the same direction as the web to the crystal substrate, such that the line at which the uncovered crystal plane of the recess touches the main area of the crystal substrate runs through the common connection region.

35. A semiconductor arrangement according to claim 33,
wherein
the etching mask layer is equipped for protecting at least one further web, by means of which the micromechanical structure element to be formed is additionally connected to at least one further edge of the recess of the crystal substrate, against the etching attack and has the border additionally extending at a predeterminable angle φ′ of less than 180 degrees on both sides of at least one further connection region of the at least one further web to the crystal substrate, such that at least one further line at which at least one further uncovered crystal plane of the recess touches the main area of the crystal substrate runs through the at least one further connection region.

36. A semiconductor arrangement according to claim 33,
wherein
the border in the connection region is straight in sections.

37. The semiconductor arrangement according to claim 33,
wherein
the predeterminable angle φ is between 170 and 180 angular degrees.

38. The semiconductor arrangement according to claim 33,
wherein
the micromechanical structure element comprises a material of the crystal substrate.

39. The semiconductor arrangement according to claim 33,
wherein
the micromechanical structure element comprises layers on the crystal substrate.

40. The semiconductor arrangement according to claim 33,
wherein
the etching mask is designed for silicon, gallium arsenide, gallium phosphide or indium phosphide as material of the crystal substrate.

41. The semiconductor arrangement according to claim 33,
wherein
the etching mask is designed for etching a crystal substrate composed of silicon with one or more of the substances from the set consisting of potassium hydroxide, sodium hydroxide, lithium hydroxide, ammonium hydroxide, ethylene diamine pyrocatechol with admixture of water, pyrocatechol and pyrazine, hydrazine with water or tetramethylammonium hydroxide as etching solution.

42. The semiconductor arrangement according to claim 33,
wherein
the crystal substrate comprises silicon having a (100) or (110) wafer orientation.
